(19) United States
(12) Patent Application Publication
(10) Pub. No.: US 2004/0218363 A1
(43) Pub. Date: Nov. 4, 2004

(54) Application specific heat-dissipating apparatus that provides electrical isolation for components

(76) Inventor: Marvin Glenn Wong, Woodland Park, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/427,757

(22) Filed: Apr. 30, 2003

(51) Int. Cl. H05K 7/20

(52) U.S. Cl. 361/704; 361/700; 361/705

(57) ABSTRACT

An application specific heat sink assembly for dissipating heat from one or more electronic components is presented with a heat-dissipating substrate selected for one or more of its size, shape, mass, cost, thermal conductivity properties, environmental resistance; and one or more heat-dissipating studs. Each heat-dissipating stud may be attached to the heat-dissipating substrate such that an electronic component may be attached to each heat-dissipating stud with the heat-dissipating stud providing CTE transition between the heat-dissipating substrate and the electronic component to be cooled. The heat-dissipating studs may selectively provide electrical conduction or isolation to an electronic component to be cooled.

### BACKGROUND OF THE INVENTION

Electronic components, such as integrated circuits or printed circuit boards, are becoming more and more common in various devices. For example, central processing units, interface, graphics and memory circuits typically comprise several integrated circuits. During normal operations, many electronic components, such as integrated circuits, generate significant amounts of heat. If the heat generated during the operation of these and other devices is not removed, the electronic components or other devices near them may overheat, resulting in damage to the components or degradation of component performance.

In order to avoid such problems caused by over heating, heat sinks or other heat-dissipating devices are often used with electronic components to dissipate heat. One must balance the heat-dissipating requirements of a heat sink with other factors. Heat sinks may crack, damage or separate from the electronic components they are attached to if the heat sink has a coefficient of thermal expansion significantly different from the electronic component. Also, many heat sink materials are relatively heavy. If the electronic component the heat sink is attached to is subjected to vibration or impact, the weight of the heat sink attached to the electronic component may crack, damage or cause the heat sink to separate from the electronic component to which it is attached.

Frequently, more than one electronic component on a printed circuit board, multi-chip module or electronic system requires heat dissipation. It would be advantageous for more than one component to be able to utilize a single heat-dissipating device, in order to optimize system cost, weight, size, and other features. However, different die on a printed circuit assembly or within a multi-chip module may have different coefficients of thermal expansion or heat dissipating requirements. It would be advantageous to provide a heat-dissipating device that is capable of accommodating various different requirements to more than one device requiring heat-dissipation.

Frequently in microelectronics and microwave electronic components, there is an increased heat-dissipating need that can be readily met with the use of a heat pipe, which can provide thermal conduction capabilities of 10-30 times or more than that of a planar heat sink device. However, such a structure may create excessive mechanical stresses due to large CTE mismatching with the die, multi-chip modules, printed circuit assemblies or other components they are used to cool. Accordingly, there is a need in the industry for more effective CTE matching or stepping between heat sink and heat pipe devices with good thermal conductivity and the components being cooled.

Some materials provide good thermal conductivity, but are difficult to shape, expensive, heavy or have other less desirable features to a particular heat-dissipating situation. Accordingly, there exists a need in the industry for the ability to optimize heat dissipation, weight, cost, machinability and other features of heat-dissipating devices and to provide a single heat-dissipating device to more than one die or component in an electronic assembly.

There may be situations in which it is desirable for a component to be electrically insulated from the heat-sink assembly to which it is mounted. For example, if it is not desirable to have the die grounded through the body of the heat sink assembly. There are other situations, e.g., controlled grounding for high frequency applications or to protect against capacitive coupling, in which case it is desirable to have the component electrically connected with the heat sink. Thus, it would be desirable to provide a heat-dissipating assembly with the ability to selectively attach the component to be cooled to the heat-dissipating assembly via electrically conductive or nonconductive means.

### SUMMARY OF THE INVENTION

An apparatus and method for optimizing heat dissipation, CTE matching, weight, cost, machinability, electrical conductivity or isolation or other features of a heat dissipation device.

An application specific heat sink assembly for dissipating heat from one or more electronic components is presented with a heat-dissipating substrate selected for one or more of its size, shape, mass, cost, thermal conductivity properties, environmental resistance; and one or more heat-dissipating studs. Each heat-dissipating stud may be attached to the heat-dissipating substrate such that an electronic component may be attached to each heat-dissipating stud with the heat-dissipating stud providing CTE transition between the heat-dissipating substrate and the electronic component to be cooled. The heat-dissipating studs may selectively provide electrical conduction or isolation to an electronic component to be cooled.

A method for manufacturing an application specific heat sink device for dissipating heat from one or more electronic components, which may include selecting or forming a heat-dissipating substrate or heat pipe; forming one or more heat-dissipating studs, such that each of the heat-dissipating studs may be shaped and sized to mate with an electronic device to be cooled; and attaching each of the heat-dissipating studs to the substrate. An electronic device to be cooled may be attached to each heat-dissipating stud. The heat-dissipating studs may selectively be electrically conductive or isolating to the electronic components to be cooled.

Other aspects and advantages of the present invention will become apparent from the following detailed description, taken in conjunction with the accompanying drawings, illustrating by way of example the principles of the invention.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 illustrates a first embodiment of a heat-dissipating device in accordance with the present invention;

FIG. 2 illustrates a second embodiment of a heat-dissipating device in accordance with the present invention;

FIG. 3 illustrates a third embodiment of a heat-dissipating device in accordance with the present invention;

FIG. 4 illustrates a flow chart for manufacturing a heat-dissipating device in accordance with the first embodiment of the present invention;

FIG. 5 illustrates a flow chart for manufacturing a heat-dissipating device in accordance with the second embodiment of the present invention;

FIG. 6 illustrates a flow chart for manufacturing a heat-dissipating device in accordance with the third embodiment of the present invention;

FIG. 7 illustrates a top plan view of an integrated circuit device package according to a fourth embodiment of the invention prior to encapsulation

FIG. 8 illustrates a cross-sectional view of the integrated circuit device of FIG. 7 taken along line 8-8;

FIG. 9 illustrates a fifth embodiment of a heat-dissipating device for dissipating heat from more than one component in accordance with the present invention;

FIG. 10 illustrates a flow chart for manufacturing a heat-dissipating device in accordance with the fifth and sixth embodiments of the present invention;

FIG. 11 illustrates a cross-sectional view of more than one integrated circuit attached to a heat-dissipating device prior to encapsulation in accordance with a sixth embodiment of the present invention;

FIG. 12 illustrates a seventh embodiment of a heat-dissipating device for dissipating heat from a component in accordance with the invention;

FIG. 13 illustrates a cross-sectional view of more than one integrated circuit attached to a heat-dissipating device prior to encapsulation in accordance with a eighth embodiment of the present invention;

FIG. 14 illustrates a flow chart for manufacturing a heat-dissipating device in accordance with the eighth embodiment of the present invention;

FIG. 15 illustrates a ninth embodiment of heat-dissipating device electrically conductive and electrically non-conductive heat-dissipating studs in accordance with the present invention; and

FIG. 16 illustrates a flow chart for manufacturing a heat-dissipating device with a non-conductive heat-dissipating stud in accordance with the ninth embodiment of the present invention.

### DETAILED DESCRIPTION

As shown in the drawings for purposes of illustration, the present invention relates to techniques for providing a heat-dissipating device in which the various features of the device, e.g. thermal conductivity, precise tolerances, CTE matching with the part to be cooled, environmental resistance, low mass, good bondability, cost, machinability, etc., may be selectively optimized. Optimizing various features of a heat sink device may be accomplished with a heat sink of more than one material, creating an application specific heat sink structure capable of meeting different requirements in different locations more readily than a monolithic heat sink structure.

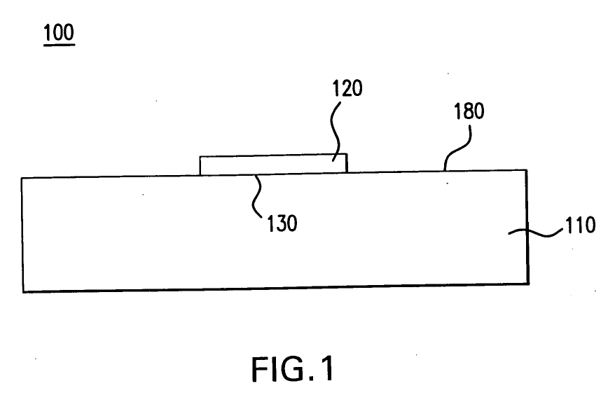

Turning now to the drawings, FIG. 1 illustrates a heat dissipation device according to a first embodiment of the present invention. A heat dissipation substrate 110 is provided. The heat dissipation substrate 110 may be selected from any known heat sink material, alloy or combination thereof, such as Aluminum Silicon Carbide, Copper, Aluminum, carbon/metal composite, ceramic or other known heat sink material. By way of example only, AlSiC may be selected for its heat conducting qualities and low weight. A heat-dissipating stud 120 may be formed by stamping, machining, etching or laser cutting from any known heat sink material, alloy or combination thereof, such as copper, tungsten, molybdenum, aluminum, copper/molybdenum/copper or other known heat sink material.

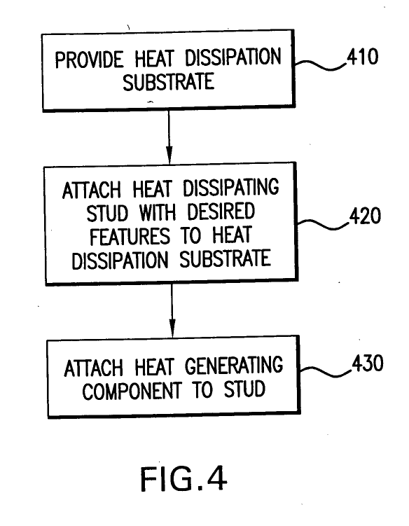

Heat stud 120 may be selected in order to have a CTE (coefficient of thermal expansion) that is relatively close to the device (integrated circuit chip, integrated circuit package, integrated circuit module, printed circuit board, etc.) to which it is to be attached. As shown in the flow chart in FIG. 4, the heat dissipation stud 120 may be attached to the surface 180 of the heat dissipation substrate 110 at a predetermined location 130 by any known means of attachment, such as brazing, soldering, adhesive bonding, press fit, screws, rivets, welding, cold diffusion under high pressure, diffusion bonding, or a thermally conductive metallic adhesive. The heat-dissipating stud 120 is precisely shaped by means of machining, stamping, etching or laser cutting and attached to the heat dissipation substrate 110 at a predetermined location 130.

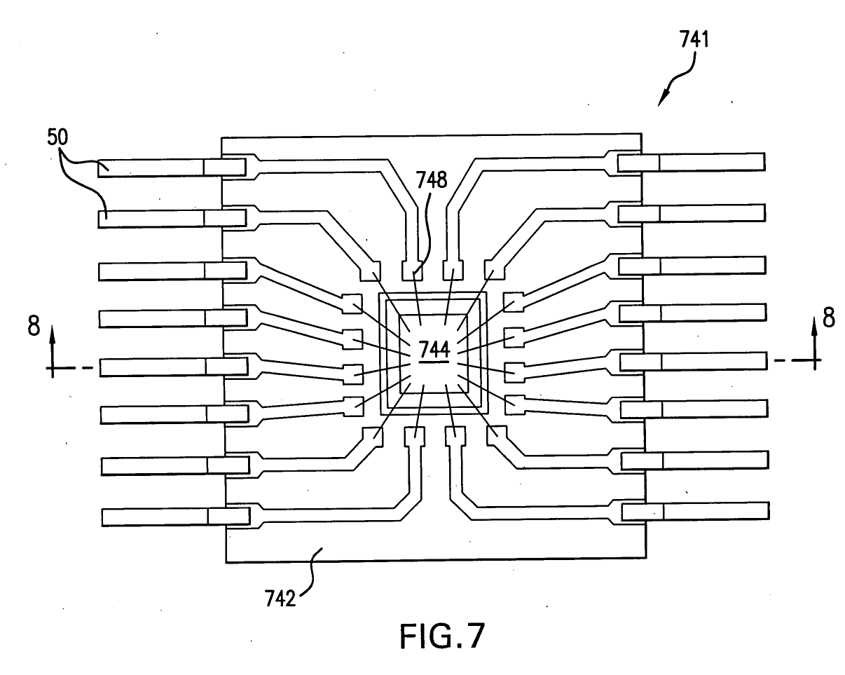

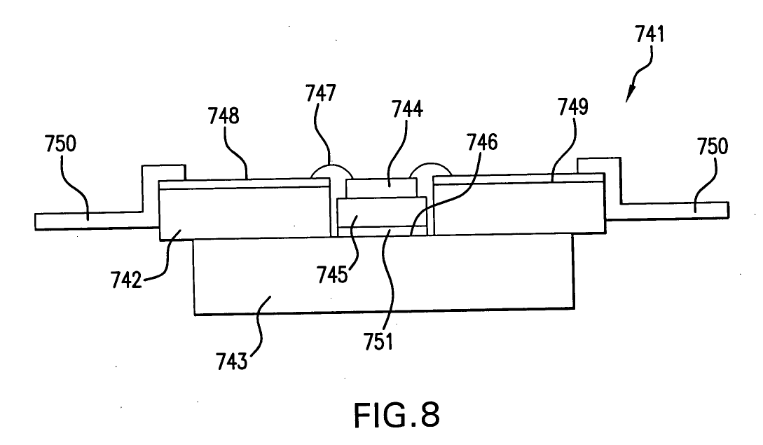

As the application specific heat sink of the present invention is versatile, various heat-dissipating substrates 110 of various materials and sizes may be kept on hand. Various heat-dissipating studs 120 of various materials and sizes may be kept on hand. Thus, the manufacturer of the device to be cooled (one exemplary embodiment shown in FIGS. 7-8) may select the substrate 110 and stud 120 for a particular heat-dissipating application by feature requirements, cost, low mass, good thermal conductivity, precise tolerances, etc. In such a case, as shown in FIG. 4, the manufacturer may select 410 the substrate 110, select the stud 120 and select an appropriate attachment method 420 as required by the particular application in order to optimize the heat sink features to the application, while minimizing heat sink costs. The device to be cooled may be attached to the stud 420. It should be noted, that the stud 120 might be attached to the device to be cooled before the stud 120 is attached to the substrate 110.

Alternatively, the manufacturer may keep various heat-dissipating substrates 110 of varying materials and sizes on hand or order from a supplier. Once the heat-dissipating substrate 110 is selected 410 for a particular application, a customized heat-dissipating stud 120 may be fabricated to specific size, thermal conductivity requirements, etc. After the stud 120 is manufactured, it may be attached 420 by any attachment method appropriate to the application. This embodiment may permit the substrate 110 to be of a material, alloy, or composite that is not readily machinable, but has other desirable heat sink features, such as good thermal conductivity, inexpensive, low mass, etc, while the stud 120 may provide other features, such as improved CTE matching with the device to be cooled, more precise machinability for sizing to match the device to be cooled, etc. The studs may also be used to obtain relative CTE matching with each respective die. It should be noted that precise CTE matching is not usually required, it is sufficient to have relatively close CTE's, as disclosed in U.S. Pat. No. 5,886,407, Polese et al., which is hereby incorporated in this Specification by reference.

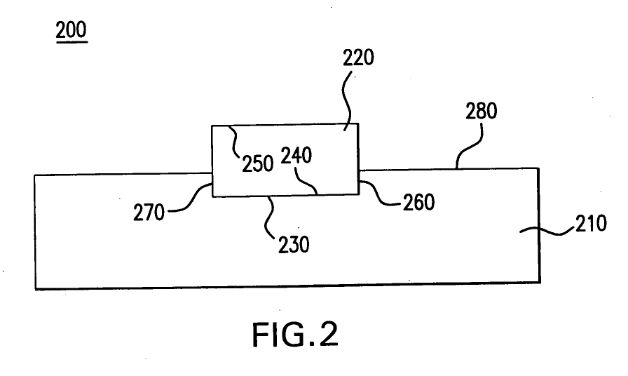

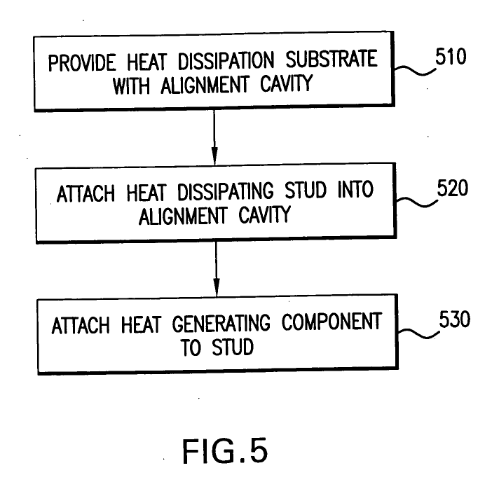

FIG. 2 shows a heat-dissipating device according to a second embodiment of the present invention. In FIG. 2, a heat-dissipating substrate 210 is provided with an alignment cavity 230 for aligning and attaching a heat-dissipating stud 220. The heat-dissipating substrate 210 may be formed by any known method, such as, machining or stamping. The cavity 230 may be formed in substrate 210 by machining or coining/stamping. As shown in the flow chart of FIG. 5, once the substrate is selected 510, the stud 220 may be attached 520 in the alignment cavity 230 by means of brazing, soldering, adhesive bonding, diffusion bonding, cold diffusion under high pressure, a thermally conductive metallic adhesive or other known attachment means. The device to be cooled (not shown) may be attached 530 to the stud 220 by means of any standard die attach method, including epoxy or eutectic die attach. This embodiment may provide for more precise alignment of the stud 220 on the substrate 210.

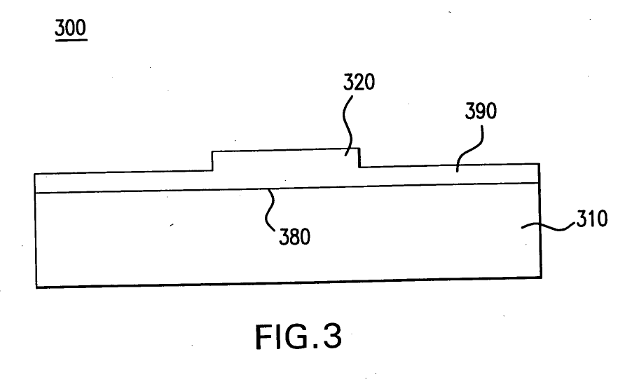

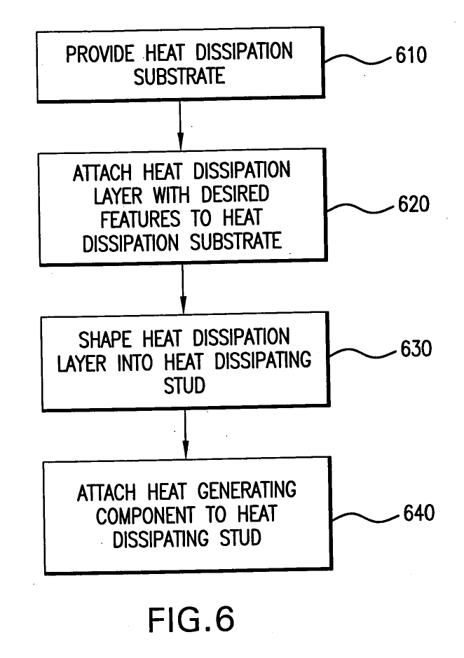

FIG. 3 shows a heat-dissipating device according to a third embodiment of the present invention. In FIG. 3, a heat-dissipating substrate 310 is provided of a predetermined size and material, metal, alloy or composite for precise requirements of a particular heat-dissipating application. As shown in FIG. 6, after the substrate is selected 610, a layer 390 of a material selected to form a heat-dissipating stud 320 is attached 620 by any known attachment means, such as brazing, soldering, adhesive bonding, diffusion bonding, vacuum hot pressing, etc. After the layer 390 is attached, a stud 320 of a predetermined size for mating with the device to be cooled is formed 630 by machining, laser cutting, chemical etching, or other known process at a predetermined location 330 on a top surface of layer 390. After the heat-dissipating stud 320 is formed in layer 390, the device to be cooled may be attached 640. The heat-dissipating stud is shaped to fit the electronic device to be cooled.

An application of the above-described heat-dissipating assembly elements in an integrated circuit device-cooling situation will now be described with reference to FIGS. 7 and 8. The integrated circuit device 741 comprises an electrical interconnect support structure 742 made of one or more layers of relatively inexpensive dielectric material such as polyamide or other polymer dielectrics, or epoxy materials having a relatively high CTE. The support structure 742 supports a heat-dissipating substrate 743 chosen for application specific qualities as described previously with respect to substrates 110, 210, and 310 and FIGS. 1-8.

A heat-dissipating stud 745 rising from the upper surface 746 of the heat-dissipating substrate 743 supports a microchip or die 744. The heat-dissipating stud 745 is manufactured separately from the heat-dissipating substrate 743 and then attached to the heat-dissipating substrate 743 by brazing, resistance welding, ultrasonic welding, pressing, i.e., cold fusion under high pressure, soldering, adhesive bonding, press fit, screws, rivets, diffusion bonding, or with use of an adhesion layer 751 of thermally conductive adhesive material or other thin adhesion material of a thickness to be determined by thermal performance requirements. A series of wire-bonds 747 connect contact points on the die 744 to metalization 748 patterned onto the surface 749 or within the body of support structure 742. The metalization connects to a plurality of leads 750 extending outward from the integrated circuit device 741. Heat-dissipating substrate 743 may be sized/shaped such that it may form part of the encapsulation structure, not shown.

It should be noted that in order to reduce heat-dissipating expenses in integrated circuit devices, the heat-dissipating substrate 743 may be selected from various generic materials, sizes and shapes, selected for it heat-dissipating qualities, low mass, environmental conditions resistance, price, etc. In order to distribute and reduce the mechanical stress at the junction of the various components of the device, the materials used for the support structure 742 are selected to have intermediate CTE's between the heat-dissipating substrate 743 and the metalization 748. The heat-dissipating stud 745 is selected from various materials to provide an intermediate CTE between the heat-dissipating substrate 743 and the integrated circuit die 744, along with other desired application specific features such as customizing of CTE matching to die, sizing, environment resistance, price, mass, etc.

The present invention may permit an end user to precisely select various features of a heat sink device to a particular application. The main body of the heat sink, or the substrate, may be of a generic size, shape and material to optimize selected features of the heat sink, such as thermal conductivity, low mass, inexpensive material, inexpensive manufacturing processes, environmental resistance, bondability, etc. While the interface surface, or slug, may be selected of a material, size and shape or made customized to the particular application, in order to optimize selected features, such as improved CTE matching with the device to be cooled, bondability, machinability to precise tolerances, etc.

It should be noted that the application specific shape of the heat-dissipating stud might be formed before or after it is attached to the heat-dissipating substrate. Also, the heat-dissipating stud may be attached to the device to be cooled before or after it is attached to the heat-dissipating substrate. Also, although FIGS. 7-8 illustrate an integrated circuit device 744 being cooled, the present invention is just as applicable to printed circuit boards, multi-chip modules, prepackaged devices, etc. without deviating from the basic concepts of the present invention.

Embodiments one-four are also applicable in a situation in which the heat-dissipating substrate may be utilized to cool more than one integrated circuit, die, printed circuit assembly or components in a multi-chip module. Basically, more than one electronic component in an assembly may utilize a single heat-dissipating substrate with different heat-dissipating studs being interposed between each electronic component to be cooled and the heat-dissipating substrate.

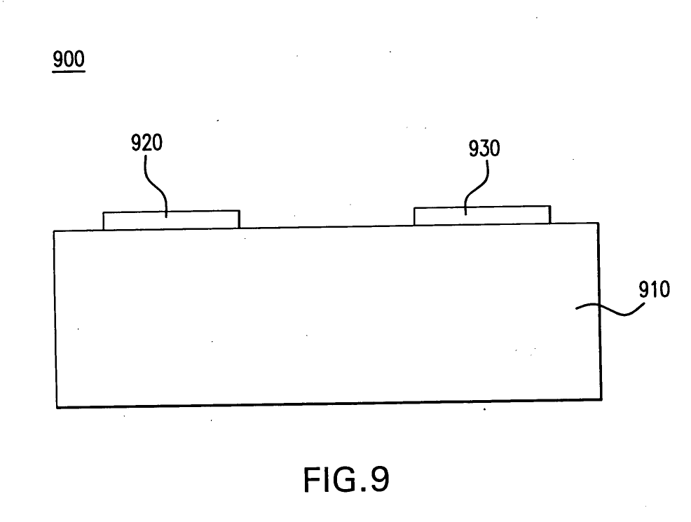

By way of exemplary illustration only, FIG. 9 shows a heat-dissipating apparatus according to a fifth embodiment of the present invention, in which a first heat-dissipating stud 920 and a second heat-dissipating stud 930 are attached to a heat-dissipating substrate 910. Heat-dissipating studs 920 and 930 are selected or formed from similar or different materials for specific desired features, such as CTE matching with first and second die or electronic assemblies (not shown), as taught herein with respect to FIGS. 1-8.

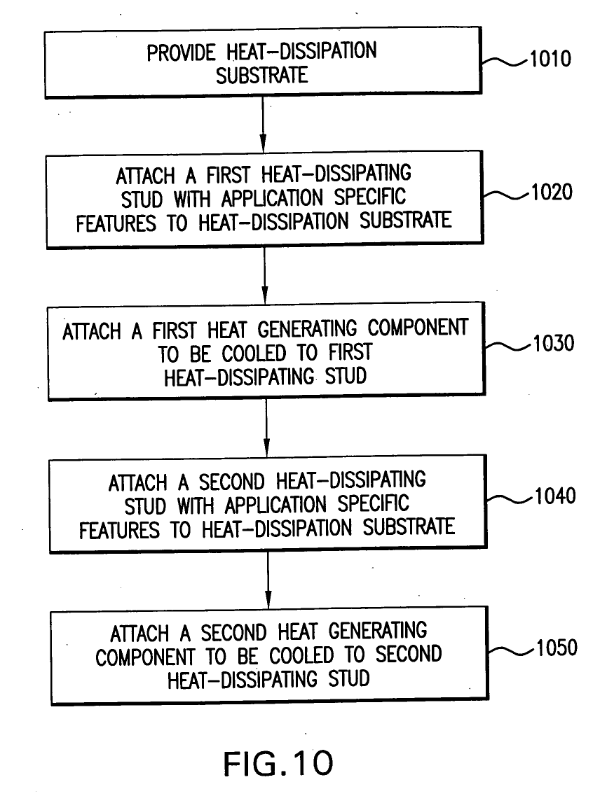

As shown in FIG. 10, heat-dissipating apparatus 900 may be manufactured by selecting from various generic substrates of varying sizes, shapes and materials or forming a substrate 910 from a specific heat-dissipating material selected for application specific features as taught with respect to FIGS. 1-8 (1010). Heat-dissipating studs 920 and 930 may be formed of similar or different materials, selected for applications specifically desired features as taught herein with respect to FIGS. 1-8 and attached to substrate 910 (1020 and 1040). Electronic components (not shown in FIG. 9) are attached to heat-dissipating studs 920 and 930. These steps may be formed in any order and any or all of the substrate 910 or studs 920 and 930 may be generic components on hand and selected and assembled for a specific application or custom fabricated to a specific application.

It should be noted that studs 920 and 930 might be formed by similar or different methods and of similar or different materials, depending on the specific desired features or requirements of the electronic component to be attached to each stud. There may be more than two heat-dissipating studs attached between the heat-dissipating substrate 910 and individual heat-generating devices or areas of an integrated circuit or multi-chip module. Also, heat-dissipating studs may be attached on both the top and the bottom surface of the heat-dissipating substrate, limited only by proximity, heat-dissipation requirements, size, weight and other devices in an assembly with heat dissipation requirements.

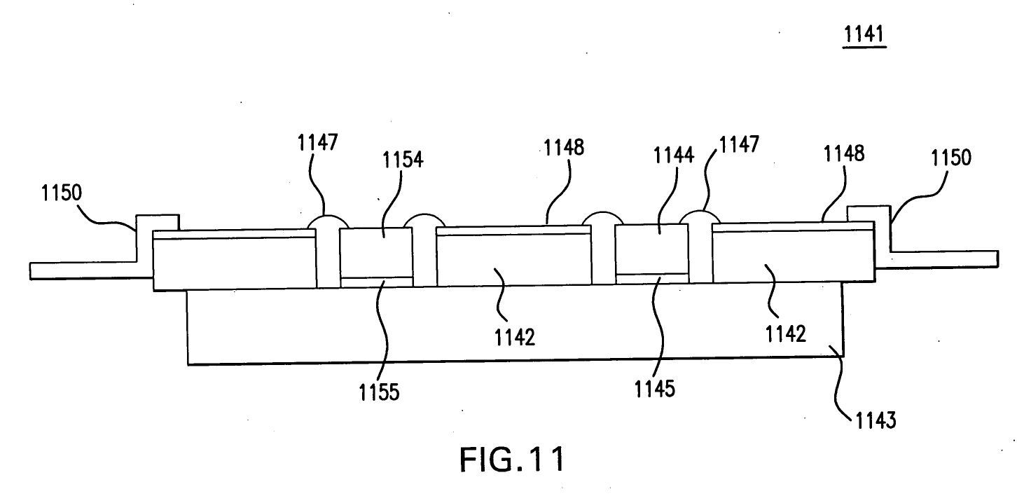

FIG. 11 illustrates an electronic assembly 1141 comprising an electrical interconnect support structure 1142 made of one or more layers of dielectric material such as polyamide or other polymer dielectric or epoxy materials. The support structure 1142 is attached to a heat-dissipating substrate 1143 made of a heat-dissipating material chosen for application specific qualities and features as described herein with respect to FIGS. 1-8.

Two or more microchips or die 1144 and 1154 are supported by heat-dissipating studs 1145 and 1155, respectively, rising from the upper surface of heat-dissipating substrate 1143. Heat-dissipating studs 1145 and 1155 may be manufactured separately from heat-dissipating substrate 1143 and attached to heat-dissipating substrate 1143 by brazing, resistance welding, ultrasonic welding, pressing, i.e., cold fusion under high pressure, soldering, adhesive bonding, press fit, screws, rivets, diffusion bonding or by and adhesion layer (not shown) of thermally conductive adhesive material or other thin adhesion material of a thickness to be determined by thermal performance requirements. A series of wire-bonds 1147 connect contact points on the die 1144 and 1154 to metalization layer or layers 1148 patterned on the surface or within the body of support structure 1142. The metalization connects to a plurality of leads 1150 extending from the electronic assembly or multi-chip module 1141. Heat-dissipating substrate 1143 may be sized/shaped such it may form part of an encapsulation structure for the electronic assembly (not shown).

In order to reduce the cost of the electronic assembly or multi-chip module 1141, the heat dissipating substrate 1143 may be selected from various generic materials, sizes and shapes, selected for its thermal conductivity, low mass, environmental resistance, price, etc. In order to distribute and reduce the mechanical stress at the junction of the various components of the assembly, the materials used for the support structure 1142 may be selected to have intermediate CTEs between the heat-dissipating substrate 1143 and the metalization layer 1148. The heat-dissipating studs 1145 and 1155 may be selected from various materials to provide an intermediate CTE between the heat-dissipating substrate 1143 and the die 1144 and 1154, along with other desired application specific features such as customizing of CTE matching to die, sizing, environment resistance, price, mass, machinability, etc.

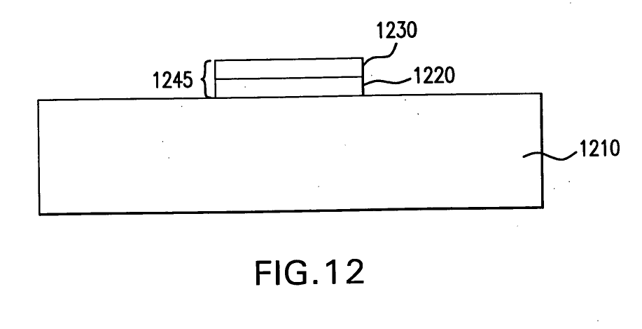

With reference now to FIG. 12, an efficient heat-dissipating substrate 1210 is shown. Substrate 1210 may be a planar substrate of an efficient thermally conductive material, a heat sink with fans or a substantially planar heat pipe. There may also be a heat-dissipating stud 1245, which may be made of a heat-dissipating layer 1230 have relatively good CTE matching with the electronic component or die to be attached thereto. The heat-dissipating stud 1245 may also include an intermediate layer 1220, which may be selected to provide a CTE that is between the CTE of layer 1230 and that of the heat-dissipating substrate 1210.

If the CTE of a heat-generating electronic component and the substrate 1210 are too different, the mismatch in CTEs may put excessive mechanical stresses on the assembly during thermal cycling. Therefore, the stud 1245 may be made of two or more layers with gradually stepped CTEs between that of the substrate 1210 and the CTE of the device to be cooled in order to decrease joint stresses due to CTE mismatches. This embodiment may also be used in an assembly in which a single heat-dissipating substrate or heat pipe is used to cool more than one electronic device, component, multi-chip module, or similar assembly. The intermediate layer 1220 and the heat-dissipating layer 1230 may be formed and attached to each other and substrate 1210 and the electronic component to be cooled by any method as discussed above with respect to FIGS. 1-6. The stud 124 may include more than two layers to provide finer CTE stepping in cases of extreme CTE mismatch between the heat-dissipating substrate 1210 and the device to be cooled.

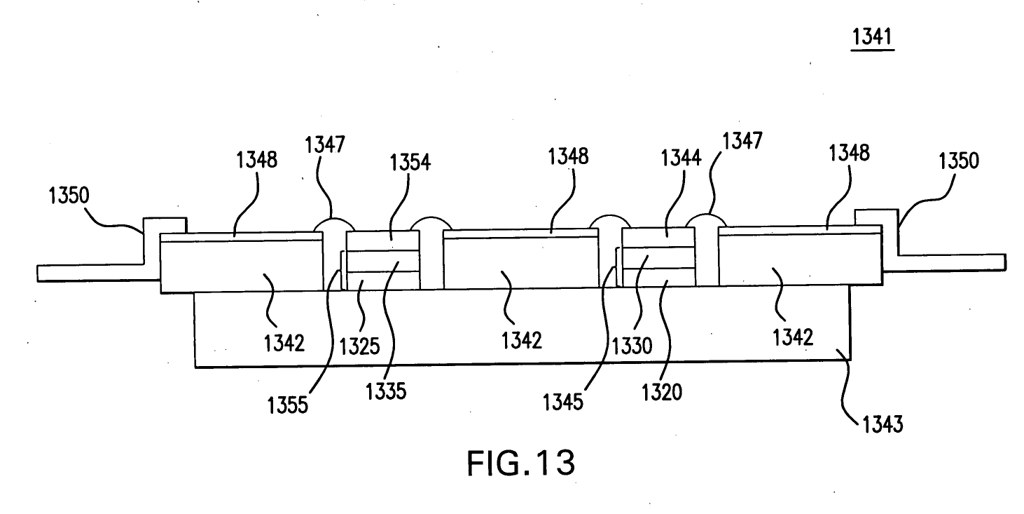

FIG. 13 illustrates a cross-sectional view of an electronic assembly 1341 comprising an electrical interconnect support structure 1342 made of one or more layers of dielectric material such as polyamide or other polymer dielectric or epoxy materials. The support structure 1342 is attached to a heat-dissipating substrate 1343. Heat-dissipating substrate 1343 may be chosen for application specific qualities and features as described herein with respect to FIGS. 1-12, specifically, it may comprise any known heat sink material, a heat sink with fins, or a heat pipe structure made of any known heat-dissipating materials and means. Heat-dissipating substrate 1343 may, depending on the application be a generic, off the shelf component selected for application specific qualities, such as, by way of example only, thermal conductivity, low mass, price, environmental resistance, bondability, etc.

Two or more micro-chips or die 1344 and 1354 are supported by heat-dissipating studs 1345 and 1355, respectively, rising form the upper surface of heat-dissipating substrate 1343. Heat-dissipating studs 1345 and 1355 may be manufactured separately from heat-dissipating substrate 1343 and attached to heat-dissipating substrate 1343 by brazing, resistance welding, ultrasonic welding, pressing, soldering, adhesive bonding, press fit, screws, rivets, diffusion bonding, cold fusion under high pressure or by an adhesion layer (not shown) of thermally conductive adhesive material or other thin adhesion material of a thickness to be determined by thermal performance requirements.

A series of wire-bonds 1347 connect contact points on the die 1344 and 1354 to metalization layer or layers 1348 patterned on the surface or within the body of support structure 1342. The metalization connects to a plurality of leads 1350 extending from the electronic assembly or multi-chip module 1341. Heat dissipating substrate 1342 may form part of an encapsulation structure (not shown) for the electronic assembly.

Studs 1345 and 1355 may be made of a layer 1330 and 1335, respectively to provide relative CTE matching with the devices 1344 and 1354, respectively. Depending of the CTE difference between devices to be cooled, 1344 and 1354, and the heat-dissipating substrate 1342, studs 1345 and 1355 may include an intermediate layer 1320 and 1325, respectively, which may provide further gradual stepping between the CTE of the substrate 1343 and the CTE of layers 1330 and 1335, in order to decrease mechanical stresses on the assembly during thermal cycling. Studs 1345 and 1355 may be formed of any of the techniques described with reference to FIGS. 1-6. Specifically, studs 1345 and 1355 may be formed by any of the methods with respect to FIGS. 1-6.

The layers of the studs may be formed and attached to the substrate separately and of differing layers or simultaneously and of the same layers, depending on the specific CTE matching requirements of each of the components 1344 and 1354. Alternatively, substrate 1343 may be manufactured and an initial CTE intermediate layer formed thereon. When the application design and location of the various components 1344 and 1354 is determined, the intermediate layers of the stud may be formed by chemical etch, laser cutting, or other known means and then the CTE matching layers 1330 and 1335 between the intermediate layers may be formed and attached of similar or different material, depending on the CTE matching requirements of the specific application.

In order to reduce the cost of the electronic assembly 1341, the heat-dissipating substrate 1343 may be selected for its thermal conductivity, low mass, environmental resistance, price, etc. from various generic materials, sizes and shapes. In order to distribute and reduce mechanical stress at the junction of various components of the assembly, the support layer 1342 may be a two-layer structure (not shown) similar to the studs 1345 and 1355. The layer adjacent to the substrate 1343 may be of the same material and formed during the same process as the intermediate layers 1320 and 1325 of studs 1345 and 1355. This layer may be formed into the bottom layer 1320 and 1330 of studs 1345 and 1355 and the bottom layer of support structure 1342 by chemical etch or other similar means. Then the top layers 1330 and 1335 of studs 1345 and 1355 may be formed and attached to the intermediate layers 1320 and 1325 and the dielectric material may be formed and attached to created support structure 1342. It should be noted that these steps might be performed in a different order to optimize process and assembly efficiencies.

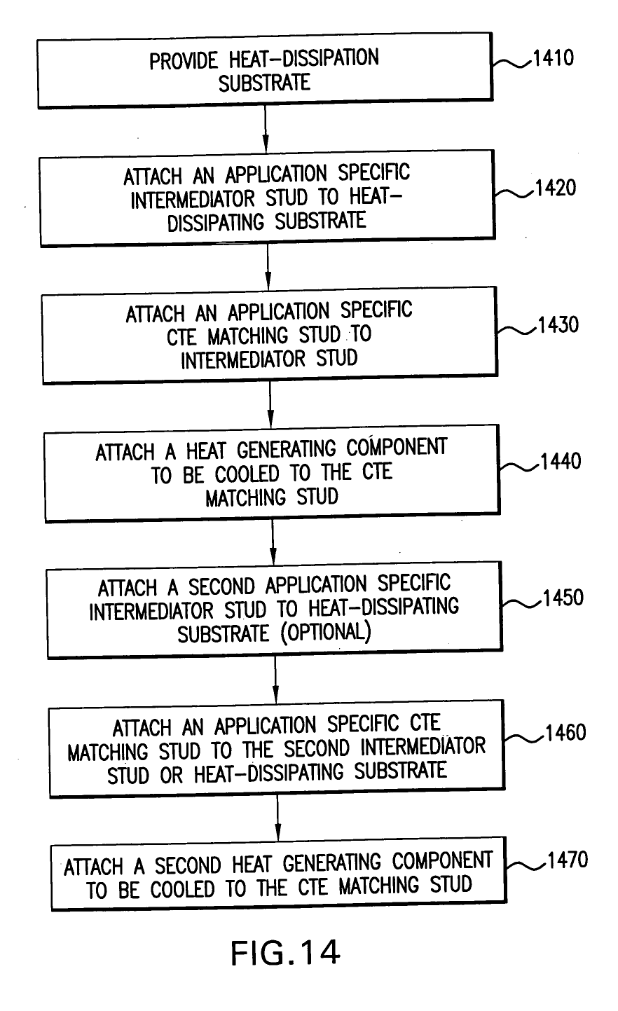

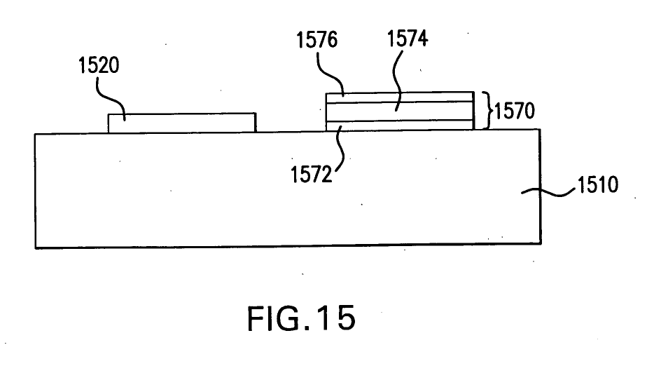

FIG. 15 shows a heat-dissipating substrate 1510, which may be a planar substrate of a thermally conductive material, a heat sink with fans or a substantially planar heat pipe, as described above with respect to FIGS. 1-14. There may be an electrically conductive heat-dissipating stud 1520 attached to heat-dissipating substrate 1510. Heat-dissipating stud 1520 may be formed and attached to heat-dissipating substrate 1510 by any means described with respect to FIGS. 1-6. An electronic component (not shown) requiring electrical conduction and heat-dissipation, may be attached to heat-dissipating stud 1520.

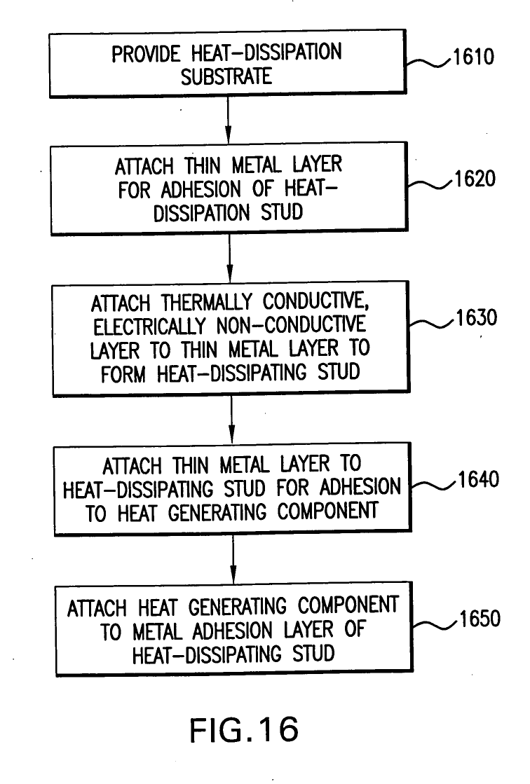

Turning now to the flow chart of FIG. 16, there may also be a heat-dissipating, electrically non-conductive stud 1570 attached to heat-dissipation substrate 1510 (1610). Thermally conductive, electrically non-conductive stud 1570 may be formed of a central layer 1574, which is thermally conductive and electrically nonconductive. Central layer 1574 may be formed of a material selected to have a CTE relatively close to the CTE of the heat-generating electronic component to be cooled, such a ceramic or composite, e.g., Macor, which is manufactured by Corning. Thermally conductive, electrically nonconductive central layer 1574 may be attached to the heat-dissipating substrate 1510 (1630) by a very thin wettable metal adhesion layer 1572 attached to the surface of substrate 1510 (1620) between layer 1574 and substrate 1510 or by other known thermally conductive, electrically isolating adhesives, such as Supertherm 2003, 2004, 2005 and 2009 manufactured by Tra-Con, Inc.

The heat-generating electronic component to be cooled may be attached to layer 1574 (1650) by means of a very thin wettable metal adhesion layer 1576 or by and known thermally conductive, electrically isolating adhesives, such as Supertherm 2003, 2004, 2005 and 2009 manufactured by Tra-Con, Inc. attached to layer 1574 of stud 1570 (1640). The layers comprising,the thermally conductive, electrically nonconductive stud 1574 may be formed and attached to the heat-dissipating substrate 1510 by any of the methods taught herein for forming and attaching heat-dissipating stud layers, as required by the specific situation. The steps of forming and attaching the thermally conductive, electrically nonconductive stud 1570 may be performed in different orders, for example, the various layers of stud 1570 may be formed and shaped and then attached to the die and the substrate 1510.

It should also be noted that the thermally conductive, electrically nonconductive layer 1574, may comprise more than one layer, in order to provide more effective CTE stepping between the heat-dissipating substrate 1510 and the component to be cooled, if such CTE stepping is required in the specific heat-dissipating application. The attachment layers do not have to be electrically isolating, if they are sufficiently thin and the electrically isolating layer is sufficiently thick.

The heat-dissipating substrate 1510 may be a solid material selected for specific features as taught herein, a heat sink with fins, or a heat pipe. The studs 1520 and 1570 may be attached to a planar surface of the heat-dissipating substrate 1510 or attached within cavities formed on the surface of heat-dissipating substrate 1510.

Although this preferred embodiment of the present invention has been disclosed for illustrative purposes, those skilled in the art will appreciate that various modifications, additions and substitutions are possible, without departing from the scope of the invention, resulting in equivalent embodiments that remain within the scope of the appended claims. For example, the generic heat-dissipating substrate may also be a heat-dissipating substrate with fins or other common heat-dissipating physical features. Also, while examples are given to specific devices, the component to be cooled may be a die, packaged circuit, multi-chip module, individual devices within a multi-chip module, printed circuit assembly, individual components on a printed circuit assembly or other electronic components.

1. An application specific heat sink assembly for dissipating heat from one or more electronic components, the application specific heat sink device comprising:
a heat-dissipating substrate selected for one or more of its size, shape, mass, cost, thermal conductivity properties and environmental resistance; and
one or more heat-dissipating studs; wherein each heat-dissipating stud is attached to the heat-dissipating substrate such that an electronic component may be attached directly to each heat-dissipating stud; wherein the one or more heat-dissipating studs comprises a thermally conductive stud, wherein each one or more heat-dissipating studs is selectively electrically conductive or nonconductive to match the electrical requirements of a specific one of one or more electronic to be attached thereto.

2. The application specific heat sink assembly in accordance with claim 1, wherein the heat-dissipating substrate comprises Aluminum Silicon Carbide.

3. The application specific heat sink assembly in accordance with claim 1, wherein the heat-dissipating substrate comprises a carbon-metal alloy.

4. The application specific heat sink assembly in accordance with claim 1, wherein the heat-dissipating substrate comprises a ceramic.

5. The application specific heat sink assembly in accordance with claim 1, wherein the heat-dissipating stud is substantially the shape of the electronic component to be attached directly thereto.

6. The application specific heat sink assembly in accordance with claim 1, wherein the heat-dissipating substrate comprises a heat pipe.

7. The application specific heat sink assembly in accordance with claim 1, wherein the heat-dissipating substrate comprises one or more cavities on a first surface, wherein at least one heat-dissipating stud is attached to the heat-dissipating substrate within the one or more cavities on the first surface of the heat-dissipating substrate, wherein the cavity provides an alignment means.

8. The application specific heat sink assembly in accordance with claim 1, wherein one or more of the each heat-dissipating studs is formed by forming a first layer having a CTE close to the CTE of the heat dissipating substrate to a top surface of the heat-dissipating substrate and then forming one or more intermediate CTE stepping layers on the first layer; wherein the one or more intermediate CTE stepping layers provide CTE stepping transition between the CTE of the substrate and the CTE of the one or more electronic components to be cooled.

9. The application specific heat sink assembly in accordance with claim 8, wherein one or more of the heat-dissipating studs is formed by forming a layer on top of one or more of the intermediate layers; wherein the layer formed on the intermediate layer has a CTE similar to the CTE of the electronic component to be cooled.

10. An application specific heat sink assembly in accordance with claim 9, wherein one or more of the heat-dissipating studs is formed by machining, laser cutting or chemical etching.

11. The application specific heat sink assembly in accordance with claim 1, wherein one or more electronic components are attached to at least one CTE matched, thermally conductive, electrically conductive stud by a thermally conductive, electrically conductive adhesion layer.

12. The application specific heat sink assembly in accordance with claim 1, wherein one or more electronic components are attached to at least one CTE matched, thermally conductive, electrically nonconductive stud by a thermally conductive, electrically isolating adhesion layer.

13. A method for manufacturing an application specific heat sink assembly of providing heat dissipation for one or more electronic components having predetermined CTEs, comprising:
selecting a heat-dissipating substrate with a predetermined CTE;
forming one or more heat-dissipating studs, wherein each heat-dissipating stud is shaped and sized to mate with an electronic device to be cooled, wherein at least one heat-dissipating stud comprises a thermally conductive layer, wherein the at least one heat-dissipating stud is selectively electrically conductive or isolating to match the electrical requirements of a specific electronic component to be attached thereto; and
attaching the one or more heat-dissipating studs to predetermined locations on the heat-dissipating substrate.

14. The method in accordance with claim 13, wherein the heat-dissipating substrate comprises Aluminum Silicon Carbide.

15. The method in accordance with claim 13, wherein the heat-dissipating substrate is selected for one or more of the following qualities, thermal conductivity, environmental resistance, low mass, inexpensive price, or bondability.

16. The method in accordance with claim 13, further comprising the step of forming one or more cavities in a top surface of the heat-dissipating substrate; wherein one or more heat-dissipating studs is attached within the one or more cavities formed on the heat-dissipating substrate.

17. The method in accordance with claim 13, wherein the heat-dissipating substrate comprises a heat pipe.

18. The method in accordance with claim 16, further comprising the step of forming one or more cavities in a top surface of the heat-dissipating substrate; wherein one or more heat-dissipating studs is attached within the one or more cavities formed on the heat-dissipating substrate.

19. The method in accordance with claim 13, wherein the heat-dissipating substrate includes fins.

20. The method in accordance with claim 19, further comprising the step of forming one or more cavities in a top surface of the heat-dissipating substrate; wherein one or more heat-dissipating studs is attached within the one or more cavities formed on the heat-dissipating substrate.

21. The method in accordance with claim 13, wherein the at least one thermally conductive stud is formed of an electrically isolating layer attached to an electronic component with an electrically isolating adhesive.

22. The method in accordance with claim 20, wherein one or more electronic components are attached to at least one thermally conductive, electrically conductive stud by an electrically conductive adhesive layer.

23. An application specific heat sink assembly for dissipating heat from more than one electronic components, the application specific heat sink device comprising:
a heat-dissipating substrate selected for one or more of its size, shape, mass, cost, thermal conductivity properties, environmental resistance; and
more than one heat-dissipating studs; wherein each heat-dissipating stud is attached to the heat-dissipating substrate such that an electronic component may be attached to each heat-dissipating stud; wherein each heat-dissipating stud is CTE matched to an electronic component to be attached thereto, wherein each heat-dissipating stud is thermally conductive and selectively electrically insulative or conductive to match the electrical requirements of the electronic component to be attached thereto.
